(19) United States
(12) Patent Application Publication
(10) Pub. No.: US 2018/0080989 A1
(43) Pub. Date: Mar. 22, 2018

(54) ASSESSMENT METHOD FOR FLASHOVER FAULTS OF 220 KV OR HIGHER PORCELAIN LIVE TANK CIRCUIT BREAKER

(71) Applicant: MAINTENANCE & TEST CENTRE, CSG EHV POWER TRANSMISSION COMPANY, Guangzhou (CN)

(72) Inventors: Changhong ZHANG, Guangzhou (CN); Xu YANG, Guangzhou (CN); Weiguo LI, Guangzhou (CN); Weimin CHEN, Guangzhou (CN); Jieshan LI, Guangzhou (CN)

(73) Assignee: MAINTENANCE & TEST CENTRE, CSG EHV POWER TRANSMISSION COMPANY, Guangzhou (CN)

(21) Appl. No.: 15/531,735

(22) PCT Filed: Oct. 31, 2016
(86) PCT No.: PCT/CN2016/104108

§ 371 Date: May 31, 2017

(30) Foreign Application Priority Data
Mar. 11, 2016 (CN) 201610140541.3

(51) Int. Cl. G01R 31/327

(52) U.S. Cl. CPC G01R 31/3275

(57) ABSTRACT

An assessment method for flashover faults of 220 kV or higher porcelain live tank circuit breakers, including the following steps: step 1, collecting fault current waveform characteristic data from a fault current waveform in a fault oscillograph, said fault current waveform characteristic data including a time duration t1 from an instant of arc quenching to an instant of fault current initiation, a time duration t2 of the fault current, and waveform characteristics of the fault current; step 2, determining the type of the flashover fault according to the fault current waveform characteristic data: the type includes external flashover, restrike internal flashover, and internal flashover on the insulator inner. The assessment is performed based on the oscillographic fault current data. Since different types of flashover fault vary in mechanism, the waveforms thereof also show different features.

### CROSS REFERENCE TO RELATED APPLICATIONS

This application is the national phase entry of International Application No. PCT/CN2016/104108, filed on Oct. 31, 2016, which is based upon and claims priority to Chinese Patent Application No. 201610140541.3 filed on Mar. 11, 2016, the entire contents of which are incorporated herein by reference.

### TECHNICAL FIELD

The present invention relates to the technical field of circuit breakers, and in particular to a method for assessing flashover faults of 220 kV or higher T-type double-break porcelain live tank circuit breakers caused by insulation design defects. The assessment is performed based on the oscillographic fault current data. Since different types of flashover fault vary in mechanism, the waveforms thereof also show different features. Thus, the type of the flashover fault can be determined by collecting the parameters and waveform characteristics of the fault current.

### BACKGROUND

The flashover fault of the circuit breaker refers to a phenomenon where an electric discharge occurs alone the surface of a solid insulator resulting from a gas breakdown around the insulator, which leads to local overheat and carbonization on the insulator surface due to sparks or electric arcs in the flashover channel, and thereby the surface insulation is damaged. Generally, defects of the insulation design of the porcelain live tank circuit breaker will cause flashover faults. For example, when it is raining, or when the insulator is covered with dirt or ice, insufficient dry arc distance and creepage distance of the porcelain bushing will cause an external flashover fault; if the dielectric recovery strength between the arcing contacts of the circuit breaker for an AC filter, is lower than the electrical stress, which is a superposition of the AC transient recovery voltage at the supply side and the DC high voltage at the load side, then a reignition breakdown happens; a metal foreign matter in the arc extinguisher may cause a flashover fault between the contacts and the inner wall of the porcelain bushing. A severe flashover fault may cause an explosion of the arc extinguisher, resulting in the damage of the surrounding devices and even a threat against the safety, and affecting power supply. Thus, a rapid determination of the types of flashover fault is important to recovery of power supply.

At present, the analysis of the flashover fault of a double-break porcelain live tank circuit breaker and the determination of the type thereof require a series of time consuming process for troubleshooting, including, field troubleshooting and condition analysis of the primary electrical equipments, analysis of protection actions of the secondary electrical equipment, and when necessary a disassembling inspection of the faulty circuit break. Furthermore, no database has been set up, for the analysis of the circuit breaker flashover faults caused by the defects of insulation design.

The present invention proposes an assessment method for identifying the type of the flashover fault by collecting the parameters and waveform characteristics of the fault current. The system can rapidly determine the tape of the flashover fault and identify the cause of the fault. The assessment method can reduce the influence of human factor, narrow the scope of fault analysis, and improve the analysis efficiency and the management of the operation.

### SUMMARY OF THE INVENTION

In view of the above defects, an object of the present invention is to provide an assessment method for flashover faults of 220 kV or higher porcelain live tank circuit breakers caused by defections of insulation design. The assessment is performed based on the oscillographic fault current data. Since different types of flashover fault vary in mechanism, the waveforms thereof also show different features. Thus, the type of the flashover fault can be determined by collecting the parameters and waveform characteristics of the fault current.

In order to achieve the above object, the present invention employs the following technical solution.

An assessment method for flashover faults of 220 kV or higher porcelain live tank circuit breakers, including the following steps:

step 1, collecting fault current waveform characteristic data from a fault current waveform in a fault oscillograph, said fault current waveform characteristic data including a time duration t1 from an instant of arc quenching to an instant of fault current initiation, a time duration t2 of the fault current, and waveform characteristics of the fault current;

step 2, determining the type of the flashover fault according to the fault current waveform characteristic data:

condition 1: when the time duration t1 is not less than 400 ms and not greater than 2,000 ms, and at the same time a persistent breakdown current appears in the fault current waveform, then the flashover fault is an external flashover caused by the insulation design of the porcelain live tank circuit breaker;

condition 2: when the time duration t1 is not less than 7 ms and not greater than 9 ms, the time duration t2 of the fault current is less than or equal to 2 ms, and at the same time any one of a high-frequency single peak, a high-frequency single oscillating peak and a high-frequency oscillating attenuation appears in the fault current waveform, then the flashover fault is a restrike internal flashover caused by the insulation design of the porcelain live tank circuit breaker;

condition 3: when the time duration t1 is not less than 10 ms and not greater than 100 ms, and at the same time the fault current waveform is a steady normal current after multiple cycles of arcing and arc quenching, then the flashover fault is an internal flashover on the insulator inner wall caused by the insulation design of the porcelain live tank circuit breaker; and

when the fault current waveform characteristic data does not satisfy any one of the above three conditions, then the flashover fault is not a flashover fault caused by the insulation design of the porcelain live tank circuit breaker.

The condition 1 further comprises the following steps: checking the cleanliness of the surface of a porcelain bushing of the porcelain live tank circuit breaker, wherein, when the surface of the porcelain bushing is covered with ice, then the external flashover is an icing flashover; when the surface of the porcelain bushing is covered with rainwater, then the external flashover is a rain flashover; when the surface of the porcelain bushing is covered with dirt, then the external flashover is a pollution flashover.

The condition 2 further comprises: when the high-frequency single peak, the high-frequency single oscillating peak or the high-frequency oscillating attenuation appears in the fault current waveform, the restrike internal flashover is a first restrike internal flashover, a second restrike internal flashover, or a third restrike internal flashover respectively.

Furthermore, three databases related to various flashover faults of circuit breakers, including a database of waveform characteristic parameters of typical fault current, a database of fault types, and a database of cause analysis and recovery methods of faults, can be established by the present invention, and serve as a data support basis for a assessment system. The key parts are diagnosis, assessment and analysis: an assessment result is obtained where the waveform data from a fault oscillograph is classified after being compared with the characteristic parameters of the characteristic waveforms in the database, and then the report will be issued with the cause and recovery method of the fault. The system further comprises a historical data statistical system, recording and collecting the data of each flashover fault assessed by the method to achieve a data statistic, which is available to the users for reference.

Compared to the prior art, the present invention provides the following benefits: the type of a flashover caused by the defect of the insulation design of the porcelain live tank circuit breaker can be identified accurately by the present assessment method, such that misjudgments and time for analysis are reduced, and reliability of the fault analysis is improved.

### BRIEF DESCRIPTION OF THE DRAWINGS

FIG. 1 is a block diagram of a flashover fault diagnosis system for a 220 kV or higher porcelain live tank circuit breaker of the present invention;

FIG. 2 is a flowchart of a flashover fault assessment method for a 220 kV or higher porcelain live tank circuit breaker of the present invention;

FIG. 3 shows a typical waveform where the fault current is a breakdown current;

FIG. 4 shows a typical waveform where the fault current is a high-frequency single peak;

FIG. 5 shows a typical waveform where the fault current is a high-frequency single oscillating peak;

FIG. 6 shows a typical waveform where the fault current is high-frequency oscillating attenuation; and

FIG. 7 shows a typical waveform where the fault current is a steady normal current after multiple cycles of arcing and arc quenching.

### DETAILED DESCRIPTION OF THE INVENTION

The present invention will be more readily apparent from the below detailed description of the drawings and the embodiments.

### Embodiment

Provided is an assessment method for flashover faults of 220 kV or higher porcelain live tank circuit breakers, which is used for assessing the flashover faults of 220 kV or higher T-type double-break porcelain live tank circuit breakers caused by insulation design defects. Said flashover mainly refers to an external flashover or an internal flashover of the double-break circuit breaker. The external flashover can be a rain flashover, an icing flashover or a pollution flashover. The internal flashover can be a restrike or an internal flashover on the insulator inner wall. Depend on the recovery method, the restrike internal flashover is a first restrike internal flashover, a second restrike internal flashover, or a third restrike internal flashover, respectively corresponding to the high-frequency single peak, the high-frequency single oscillating peak or the high-frequency oscillating attenuation appearing in the fault current waveform.

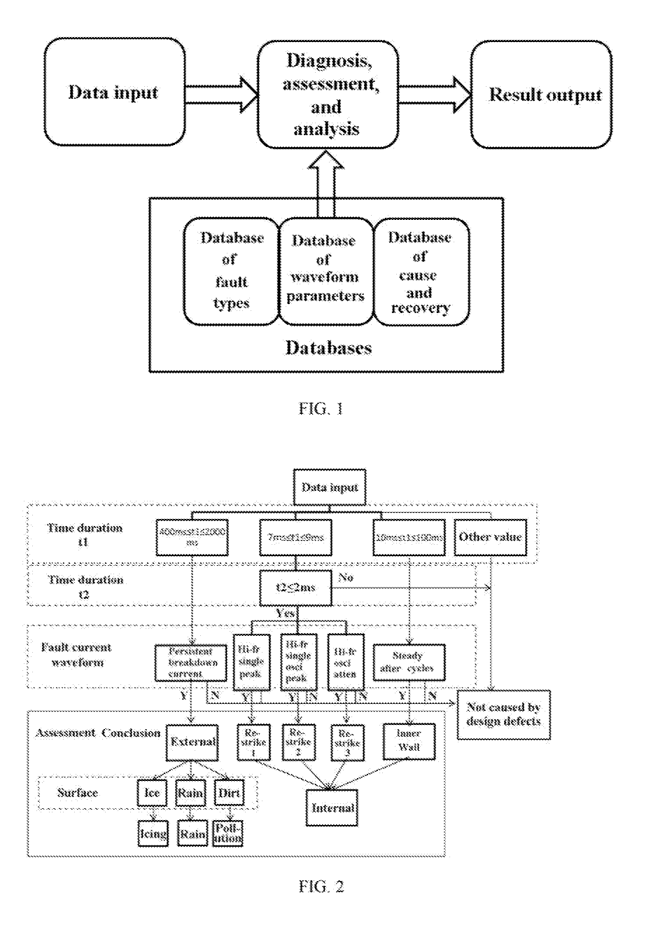

In order to assess and diagnose the flashover faults of 220 kV or higher porcelain live tank circuit breakers, a flashover fault diagnosis system for 220 kV or higher porcelain live tank circuit breaker is provided in a preferred embodiment of the present invention. As shown in FIG. 1, the system mainly consists of an input unit, a database unit, an analysis unit and a result output unit.

The input unit: The required data is from a fault current waveform in a fault oscillograph, including: 1) information of the faulty circuit breaker: the scheduling serial number, the phase, the voltage level, the type, the manufacturer and the commissioning date of the circuit breaker; 2) waveform characteristic data: the time point when a fault current occurs after the circuit breaker is disconnected (ms), peak current magnitude (A), duration (ms), waveform characteristics of the current, and cleanliness of the surface of the porcelain bushing.

The database unit: A database of fault types, a database of waveform characteristic parameters, and a database of cause analysis and recovery methods of faults are provided. For each fault type recorded in the database of fault types, a cause analysis and a recovery method are provided in the database of cause analysis and recovery method of faults correspondingly.

The analysis unit, which is used for diagnosis, analysis and assessment: The characteristic data from a fault oscillograph is classified after being compared with the characteristic parameters in the database, to determine whether it is a flashover fault and identify the type of the flashover fault.

The output unit, which is for outputting the assessment result: The assessment result is output in the form of an assessment report, including basic information of the device, type of the flashover fault, summary of possible causes of the fault, and effective methods can be taken corresponding to each cause.

Characteristic waveforms are directed to the waveform characteristic parameters of the fault current when said flashover occurs. Each type of flashover faults shows a specific waveform. The waveform characteristic parameters are stored in the database of waveform characteristic parameters, which comprises the characteristic parameters data of flashover faults, mainly including 8 types below.

As shown in FIG. 2, the assessment method comprises the following steps.

1. Collecting fault current waveform characteristic data from a fault current waveform in a fault oscillograph, said fault current waveform characteristic data including a time duration t1 from an instant of arc quenching to an instant of fault current initiation, a time duration t2 of the fault current, waveform characteristics of the fault current, and cleanliness of the surface of a porcelain bushing.

2. The fault current waveform characteristic data is compared with the characteristic parameters in the database of waveform characteristic parameters, to identify the type of the flashover fault.

The waveform characteristic parameters vary in the below seven conditions.

Condition 1: When the time duration t1, from an instant of arc quenching (when the circuit breaker is disconnected) to an instant of fault current initiation, is not less than 400 ms and not greater than 2,000 ms, and a persistent breakdown current appears in the fault current waveform, and at the same time the porcelain bushing is covered with ice. In such case, the flashover fault is an icing flashover.

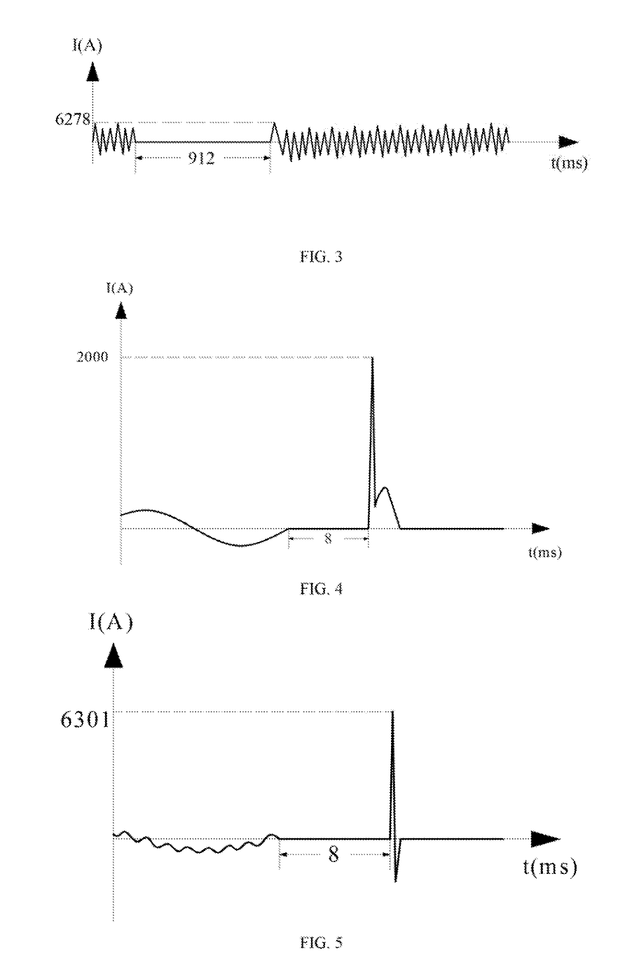

As shown in FIG. 3 where a persistent breakdown current appears in the fault current waveform, the waveform characteristics of the persistent breakdown current includes a long duration (over 2 ms), continuous alternation of peaks and valleys, and differences between the peak values and those between the valley values being small.

Condition 2: When the time duration t1, from an instant of arc quenching to an instant of fault current initiation, is not less than 400 ms and not greater than 2,000 ms, and a persistent breakdown current appears in the fault current waveform and at the same time the porcelain bushing is covered with rainwater.

In such case, the flashover fault is a rain flashover.

Condition 3: When the time duration t1, from an instant of arc quenching to an instant of fault current initiation, is not less than 400 ms and not greater than 2,000 ms, and a persistent breakdown current appears in the fault current waveform and at the same time the porcelain bushing is covered with dirt.

In such case, the flashover fault is a pollution flashover.

Condition 4: When the time duration t1, from an instant of arc quenching to an instant of fault current initiation, is not less than 7 ms and not greater than 9 ms, the time duration t2 of the fault current is less than or equal to 2 ms, and at the same time a high-frequency single peak appears in the fault current waveform.

In such case, the flashover fault is a first restrike internal flashover. As shown in FIG. 4 where a high-frequency single peak appears in the fault current waveform, the waveform characteristics includes a short duration (not greater than 2 ms), with at least two continuous peaks where no current zero between the peaks, and differences between the peak values being large.

Condition 5: When the time duration t1, from an instant of arc quenching to an instant of fault current initiation, is not less than 7 ms and not greater than 9 ms, the time duration t2 of the fault current is less than or equal to 2 ms, and at the same time a high-frequency single oscillating peak appears in the fault current waveform.

In such case, the flashover fault is a second restrike internal flashover. As shown in FIG. 5 where a high-frequency single oscillating peak appears in the fault current waveform, the waveform characteristics includes a short duration (not greater than 2 ms), with only one peak after which the current drops to zero.

Condition 6: When the time duration t1, from an instant of arc quenching to an instant of fault current initiation, is not less than 7 ms and not greater than 9 ms, the time duration t2 of the fault current is less than or equal to 2 ms, and at the same time a high-frequency oscillating attenuation appears in the fault current waveform.

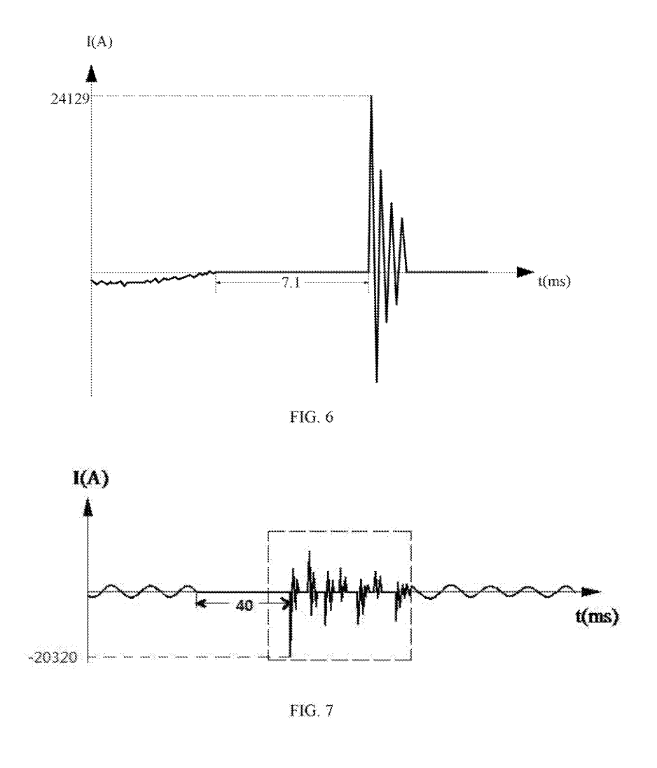

In such case, the flashover fault is a third restrike internal flashover. As shown in FIG. 6 where a high-frequency single oscillating attenuation appears in the fault current waveform, the waveform characteristics includes a short duration (not greater than 2 ms), continuous alternation of peaks and valleys, and the peak values and the valley values decrease gradually.

Condition 7: When the time duration t1, from an instant of arc quenching to an instant of fault current initiation, is not less than 10 ms and not greater than 100 ms, and at the same time the fault current waveform is a steady normal current after multiple cycles of arcing and arc quenching.

In such case, the flashover fault is an internal flashover on the insulator inner wall. As shown in FIG. 7 where the fault current waveform is a steady normal current after multiple cycles of arcing and arc quenching, the waveform characteristics is that the time duration of the fault current is uncertain, with multiple cycles of arcing and arc quenching (as indicated in the dashed box in FIG. 7).

If a flashover fault occurs in the 220 kv or higher T-type double-break porcelain live tank circuit breakers, but does not satisfy any one of the above seven conditions, then the flashover fault is not caused by the insulation design of the porcelain live tank circuit breaker.

The method can achieve a rapid determination of flashover fault by providing databases and assessment, and users can identify the cause and handle the fault in time according to the assessment result, such that misjudgments and time for analysis are reduced.

The present invention will be more readily apparent from the below detailed description of the fault current waveform in FIG. 4, wherein the diagnosis comprises the following steps.

1. Collecting Characteristic Data.

The fault current waveform as shown in FIG. 4 is collected from the fault oscillograph, comprising the following data: the time point when a fault current occurs after the arc quenching (8 ms), fault current duration (0.3 ms), waveform of the fault current (a high-frequency single peak), peak current magnitude (2,000 A), and cleanliness of the surface of the porcelain bushing (the surface is clean).

2. Data Input

Data input includes, basic information of the faulty circuit breaker as shown in Table 1, and waveform characteristic data of the fault current as shown in Table 2.

TABLE 1
Basic information of the faulty circuit breaker

| | | Scheduling serial | Phase of the |
|---|---|---|---|
| Location | Voltage level | number | fault |
| HZ Station | 500 kV | 592 | B |
| | Type of the | commissioning | Occurrence time |
| Manufacturer | circuit breaker | date | of the fault |
| XIKAI | LW15 | 2013 August | xxxx |

TABLE 2
Information of the fault

| | | | Fault current | |
|---|---|---|---|---|
| t1/ms | t2/ms | Fault current waveform | I/kA | Cleanliness |
| 8 | 0.3-0.4 | High-frequency single peak | 2 | Clean |

3. Diagnosis, Assessment and Analysis

The data in Table 2 is compared with the characteristic parameters in the database of waveform characteristic parameters, and it shows that the fault is a first restrike internal flashover caused by the insulation design.

4. Result Output

Content of the report includes: information of the faulty circuit breaker, conclusion of the assessment, cause analysis and recovery methods. The information of the faulty circuit breaker as shown in Table 3 is the output of the basic information of the faulty circuit breaker. The conclusion of the assessment is obtained in step 3. The cause analysis and recovery methods section is obtained from the database of cause analysis and recovery methods of faults, based on the fault type indicated in the conclusion.

TABLE 3
Information of the faulty circuit breaker

| | | Scheduling serial | Phase of the |
|---|---|---|---|
| Location | Voltage level | number | fault |
| HZ Station | 500 kV | 592 | B |
| | Type of the | commissioning | Occurrence time |
| Manufacturer | circuit breaker | date | of the fault |
| XIKAI | LW15 | 2013 August | xxxx |

Conclusion of the assessment: it is a first restrike internal flashover fault.

Cause of the fault: A relative high transient recovery voltage occurred between the arcing contacts; and at the same time, since the circuit breaker was under a DC/AV hybrid voltage, the grading capacitor was unable to uniformly distribute the DC voltage in the two breaks. Within 7 ms-9 ms after the arc quenching, the dielectric recovery strength between the arcing contacts, may be lower than the electrical stress which was a superposition of the AC transient recovery voltage at the supply side and the DC high voltage at the load side, and thereby a restrike occurred.

Recovery method: 1. Increasing the SF₆ gas pressure rating of the circuit breaker by 0.1-0.2 MPa, and improving the inner insulation of the arc extinguisher of the circuit breaker, which can effectively prevent the restrike. 2. Introducing a shunt gate device which can effectively control the arcing time of the circuit breaker so as to prevent the restrike.

Although the present invention is described with the specific embodiments, those skilled in the art may understand that various variations and equivalent replacements can be made to the present invention without departing from the scope of the present invention. In addition, for specific situations or applications, various modifications may be made to the present invention without departing from the scope of the present invention. Therefore, the present invention is not limited to the particular embodiments disclosed and shall include all embodiments that fall into the scope of the claims of the present invention.

1. An assessment method for flashover faults of 220 kV or higher porcelain live tank circuit breakers, wherein the method comprising:
step 1, collecting fault current waveform characteristic data from a fault current waveform in a fault oscillograph, said fault current waveform characteristic data including a first time duration t1 from a first instant of an arc quenching to a second instant of a fault current initiation, a second time duration t2 of a fault current, and a plurality of waveform characteristics of the fault current;
step 2, determining the type of a flashover fault according to the fault current waveform characteristic data:
condition 1: when the first time duration t1 is not less than 400 ms and not greater than 2,000 ms, and at the same time a persistent breakdown current appears in the fault current waveform, then the flashover fault is an external flashover caused by an insulation design of a porcelain live tank circuit breaker;
condition 2: when the first time duration t1 is not less than 7 ms and not greater than 9 ms, the second time duration t2 of the fault current is less than or equal to 2 ms, and at the same time a condition selected from the group consisting of a high-frequency single peak, a high-frequency single oscillating peak and a high-frequency oscillating attenuation appears in the fault current waveform, then the flashover fault is a restrike internal flashover caused by the insulation design of the porcelain live tank circuit breaker;
condition 3: when the time duration t1 is not less than 10 ms and not greater than 100 ms, and at the same time the fault current waveform is a steady normal current after a plurality of cycles of an arcing and the arc quenching, then the flashover fault is an internal flashover on an insulator inner wall caused by the insulation design of the porcelain live tank circuit breaker; and
when the fault current waveform characteristic data satisfy none of the condition 1, the condition 2, and the condition 3, then the flashover fault is not caused by the insulation design of the porcelain live tank circuit breaker.

2. The assessment method for flashover faults of 220 kV or higher porcelain live tank circuit breakers according to claim 1, wherein said condition 1 further comprises the following steps: checking a cleanliness of a surface of a porcelain bushing of the porcelain live tank circuit breaker, wherein, when the surface of the porcelain bushing is covered with ice, then an external flashover is an icing flashover; when the surface of the porcelain bushing is covered with rainwater, then the external flashover is a rain flashover; when the surface of the porcelain bushing is covered with dirt, then the external flashover is a pollution flashover.

3. (canceled)
